(19) United States
(12) Patent Application Publication
(10) Pub. No.: US 2022/0291711 A1
(43) Pub. Date: Sep. 15, 2022

(54) DISPLAY STANDS WITH EXPANSION SLOTS

(71) Applicant: Hewlett-Packard Development Company, L.P., Spring, TX (US)

(72) Inventor: Tao-An Chen, Taipei City (TW)

(73) Assignee: Hewlett-Packard Development Company, L.P., Spring, TX (US)

(21) Appl. No.: 17/631,620

(22) PCT Filed: Sep. 30, 2019
(86) PCT No.: PCT/US2019/053731

§ 371 Date: Jan. 31, 2022

(51) Int. Cl. G06F 1/16; G06F 1/18; G06F 3/147; H05K 7/14

(52) U.S. Cl. CPC G06F 1/1607; G06F 1/185; G06F 3/147; H05K 7/1417

(57) ABSTRACT

The present disclosure relates to display stands with an expansion slot. An example display stand can include a base portion that includes an expansion slot, an attachment mechanism to couple a display to the base portion, and a permanent connection to couple the expansion slot to the display.

### BACKGROUND

A display or monitor can include an output device that can display information in a pictorial form. The display can include a plurality of light sources that can be utilized to generate images that are displayed utilizing different combinations of the plurality of light sources. The display can be coupled to a computing device to receive images from the computing device to generate the received images utilizing the plurality of light sources.

### BRIEF DESCRIPTION OF THE DRAWINGS

FIG. 1 is an example system for a display stand with an expansion slot consistent with the present disclosure.

FIG. 2 is an example display stand with an expansion slot consistent with the present disclosure.

FIG. 3 is an example display stand with an expansion slot consistent with the present disclosure.

FIG. 4 is an example installation of an expansion card to an expansion slot within a display stand consistent with the present disclosure.

### DETAILED DESCRIPTION

Displays can be devices to display digital images. In some examples, a display can be a computing display, a laptop display, a phone display, and/or a television display. Displays can be utilized to perform a plurality of different functions. For example, displays can be coupled to computing devices to allow a user to make selections and interact with the computing device. In some examples, the display can be coupled to a separate graphical processing resource such as an expansion graphics card, express graphics card, and/or other type of graphical processing unit (GPU). In these examples, the separate graphical processing resource can be separate from a computing processing resource (e.g., processor, main processor, central processing unit (CPU), etc.) that can be utilized to execute instructions to perform functions. That is, the separate graphical processing resource can be utilized to help process the digital images to be displayed on the display while the computing processing resource can be utilized to perform other functions of the computing device.

In some examples, a graphical processing unit can be an expansion graphics card that is capable of being coupled to and removed from an expansion slot or expansion port. For example, the graphical processing unit can be a graphics expansion card (e.g., graphics express card, etc.) that can include a printed circuit board (PCB) or printed circuit assembly (PCA), a processing resource, and/or a cooling resource (e.g., fan, liquid cooling connections, etc.), In this example, the expansion slot can receive a connection interface of the graphics expansion card and provide the additional functionality of the graphics expansion card to a system (e.g., display, computing system, display system, etc.).

In some examples, a computing device can include a computing board such as a PCB that includes a main processor or central processing unit (CPU). In these examples, the PCB can include an expansion slot or express slot to receive different types of expansion cards that can be utilized to provide additional functionality to the computing device. However, the expansion slot or express slot may not be easily accessible and thus may be difficult to access in order to install or remove an expansion card such as a graphics expansion card. In this way, it can be difficult to utilize the expansion card, such as a graphics express card, for a plurality of different computing devices.

The present disclosure relates to systems and devices for display stands with an expansion slot. In some examples, the expansion slot can be enclosed within a base portion of the display stand. In some examples, the display stand can include a circuit such as a PCB or PCA that can be utilized by the display. In these examples, the circuit of the display can be positioned within the base portion of the display stand. In these examples, the expansion slot can be positioned on the circuit of the display such that a lid of the display stand can be altered to gain access to the expansion slot such that an expansion card can be coupled to the circuit of the display. In this way, a plurality of different computing devices can be coupled to the display and utilize the expansion card coupled to the expansion slot. In other examples, a plurality of different computing devices can utilize corresponding expansion cards when utilizing the display. Thus, the display stands described herein can include a more easily accessible expansion slot that can be utilized with the display compared to other display stands.

The figures herein follow a numbering convention in which the first digit corresponds to the drawing figure number and the remaining digits identify an element or component in the drawing. Elements shown in the various figures herein may be capable of being added, exchanged, and/or eliminated so as to provide a number of additional examples of the present disclosure. In addition, the proportion and the relative scale of the elements provided in the figures are intended to illustrate the examples of the present disclosure and should not be taken in a limiting sense.

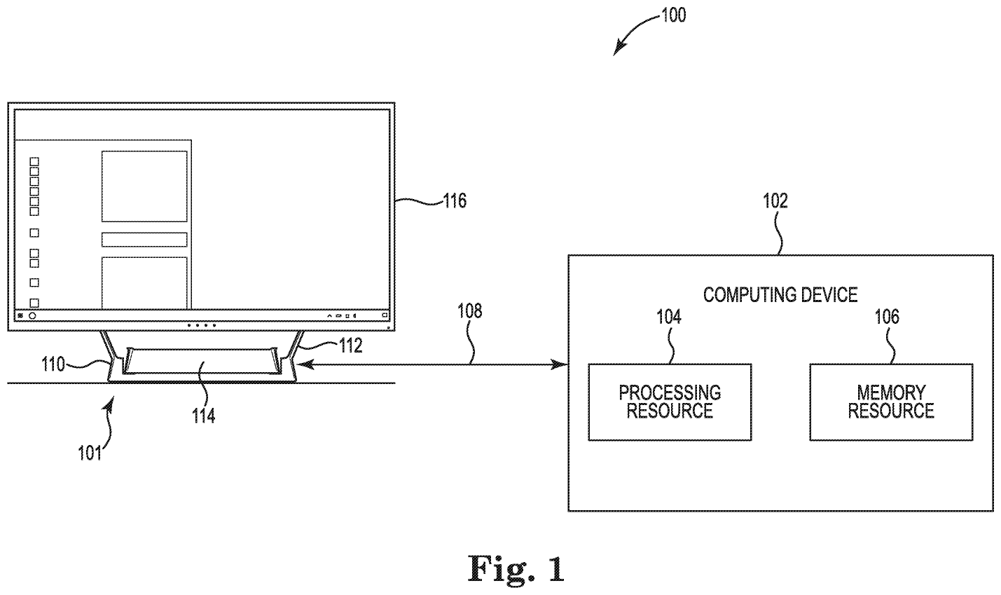

FIG. 1 is an example system 100 for a display stand 101 with an expansion slot consistent with the present disclosure. In some examples, the system 100 can include a computing device 102 that is communicatively coupled to a display 116 and/or the display stand 101 through a communication path 108. In some examples, the communication path 108 can be utilized by the computing device 102 to provide data to the display 116. For example, the computing device 102 can be utilized to generate image data, such as gaming data related to a video game being played on the computing device 102. In this example, the image data can be provided to the display 116 or computing components of the display 116 through the communication path 108. In this example, the display 116 can project the image data utilizing a plurality of light sources (e.g., light emitting diodes (LEDs), organic light emitting diodes (OLEDs), etc.).

In some examples, the communication path 108 can be a physical connection or a wireless connection between the computing device 102 and the display 116. For example, the communication path 108 can include, but is not limited to: a VGA cable, an HDMI cable, a DVI cable, universal serial bus (USB) cable, among other connections that can transfer data. In some examples, the communication path 108 can be a physical cable that includes a first port coupled to the computing device 102 and a second port coupled to the display 116 and/or computing components of the display 116 positioned within a base portion 110 of a display stand 101. For example, a PCB can be positioned within the base portion 110 of the display stand 101. In this example, the PCB can be communicatively coupled to the display 116 and can be a main PCB for the display 116 or a secondary PCB for the display 116. As used herein, a main PCB for the display 116 can include a PCB with a majority of components or provides a majority of functions while a secondary PCB for the display 116 can include a PCB with a minority of components or provides a minority of functions.

In some examples, the computing device 102 can include a processing resource 104 and a memory resource 106. Processing resource 104, as used herein, can include a number of processing resources capable of executing instructions stored by a memory resource 106. The instructions (e.g., machine-readable instructions (MRI)) can include instructions stored on the memory resource 106 and executable by the processing resource 104 to implement a particular function (e.g., generate video data, generate image date, etc.), The memory resource 106, as used herein, can include a number of memory components capable of storing non-transitory instructions that can be executed by processing resource 104.

The memory resource 106 can be in communication with the processing resource 104 via a communication link (e.g., communication path). The communication link can be local or remote to an electronic device associated with the processing resource 104. In some examples, the instructions (e.g., software, firmware, etc.) stored by the memory resource 106 can be downloaded and stored in memory resource 106 (e.g., MRM) as well as a hard-wired program (e.g., logic), among other possibilities.

In some examples, the computing device 102 can utilize the processing resource 104 and/or the memory resource 106 to execute instructions that can include corresponding images to be displayed on the display 116. In some examples, the computing device 102 can provide image data (e.g., graphics data, video data, etc.) to the computing components of the display 116 and the display 116 can decode the image to generate images on the display 116. In some examples, the image data provided by the computing device 102 can be in a format that can instruct the computing components of the display 116 to display a particular image.

As described herein, the computing components or a portion of the computing components can be positioned within the base portion 110 of the display stand 101. For example, the base portion 110 can include a PCB positioned within an enclosure of the base portion 110. In this example, the PCB can be covered by a lid portion 114 that can be raised or lowered to open or close the enclosure. In this way, the PCB or other computing components of the display 116 positioned within the base portion 110 can be more easily accessed.

In some examples, the computing components or portion of the computing components stored within the base portion 110 of the display stand 101 can include an expansion slot that can be utilized to receive an expansion card. As described herein, the expansion slot can be an electrical connector coupled to a PCB or PCA that can receive and/or couple an expansion card. For example, the expansion slot can include a PCI-Express x16 slot, AGP slot, PCI-Express x1 slot, and/or other type of physical connection interface that can receive an expansion card. As used herein, an expansion card can include a PCB or PCA that includes an electrical interface or electrical connector that can be coupled to the expansion slot. For example, the expansion card can include, but is not limited to: random access memory (RAM), interface card (e.g., Bluetooth, RAID, USB, etc.), network card, sound card, video card, graphics card, among other types of expansion cards that can be utilized to provide additional functionality to a device or system.

In some examples, the expansion slot within the base portion 110 or under the lid portion 114 can be utilized to receive a graphics expansion card (e.g., video card, etc.). As used herein, a graphics expansion card can include a PCB that includes a processing resource and/or cooling resource to process image data. For example, the graphics expansion card can be installed in the expansion slot positioned within the base portion 110 to provide additional graphics processing capability to the system 100. That is, the processing resource of the expansion card can be utilized to process image data, which can reduce processing functions of the processing resource 104 of the computing device 102.

In some examples, the computing device 102 can send image data in a first format to the computing components within the base portion 110 of the display stand 101. In these examples, the expansion card can utilize the processing resource to convert the image data from the first format to a second format that can be utilized to display corresponding images on the display 116. For example, the computing device 102 can provide image data in a first format such as, but not limited to a USB4/TB3 format. In this example, the processing resource of a graphics expansion card can convert the USB4/TB3 format to a PCIe format and the PCIe format can be utilized by the graphics expansion card process installed in the display stand 101, The graphics process provided by the graphics expansion card can be utilized to display images on the display 116. In this way, the processing resource 104 of the computing device 102 may not have to convert the image data to a different format, which can lower the processing of the processing resource 104. In addition, the images displayed by the display 116 can be a relatively higher quality as a result of the additional processing resources of the graphics expansion card. Furthermore, the processing resource 104 can be utilized to process a first type of graphics (e.g., hyper graphics, etc.) and the graphics expansion card can be utilized to process a second type of graphics (e.g., vivid graphics, etc.).

In some examples, the display stand 101 can include an arm 112 that extends from the base portion 110. As used herein, an arm 112 can include a structural protrusion from the base portion 110 utilized to couple the display 116 to the base portion 110. In some examples, the base portion 110 can be utilized to support the weight of the display 116 when the base portion 110 is positioned on a surface (e.g., desk, floor, table, etc.), In some examples, the computing components positioned within the base portion 110 can be communicatively coupled to the computing components within the display 116 and/or the light sources within the display 116. For example, the computing components within the base portion 110 can include a connection cable or connection interface that is positioned within the arm 112 of the display stand 101. In this way, the lid 114 can be utilized to more easily access a portion of the computing components of the display 116 and/or access an expansion slot positioned within the base portion 110 of the display stand 101.

In some examples, the system 100 can include an attachment mechanism to couple a display 116 to the base portion 110 of the display stand 101. For example, the attachment mechanism can be positioned on a first side of the arm 112 to couple the display 116 to the arm 112 and the arm 112 can be coupled to the base portion 110. In some examples, the attachment mechanism can include a mechanical mechanism to physically couple the display 116 to the base portion 110 and an electrical mechanism to electrically couple the display 116 to the computing components positioned within the base portion 110. In some examples, the attachment mechanism can be utilized to couple different displays 116 to the display stand 101. In other examples, the attachment mechanism can be permanently coupled to the display 116.

As described herein, the computing components positioned within the base portion 110 can be permanently coupled to the computing components positioned within the display 116. In some examples, a first portion of the permanent connection is positioned within the base portion 110 and a second portion of the permanent connection is positioned through the attachment mechanism or arm 112. For example, a first PCB positioned within the base portion 110 can be permanently coupled to a second PCB or light sources positioned within the display 116. As used herein, a permanent connection can include a connection type that is not designed to be coupled and decoupled by an end user.

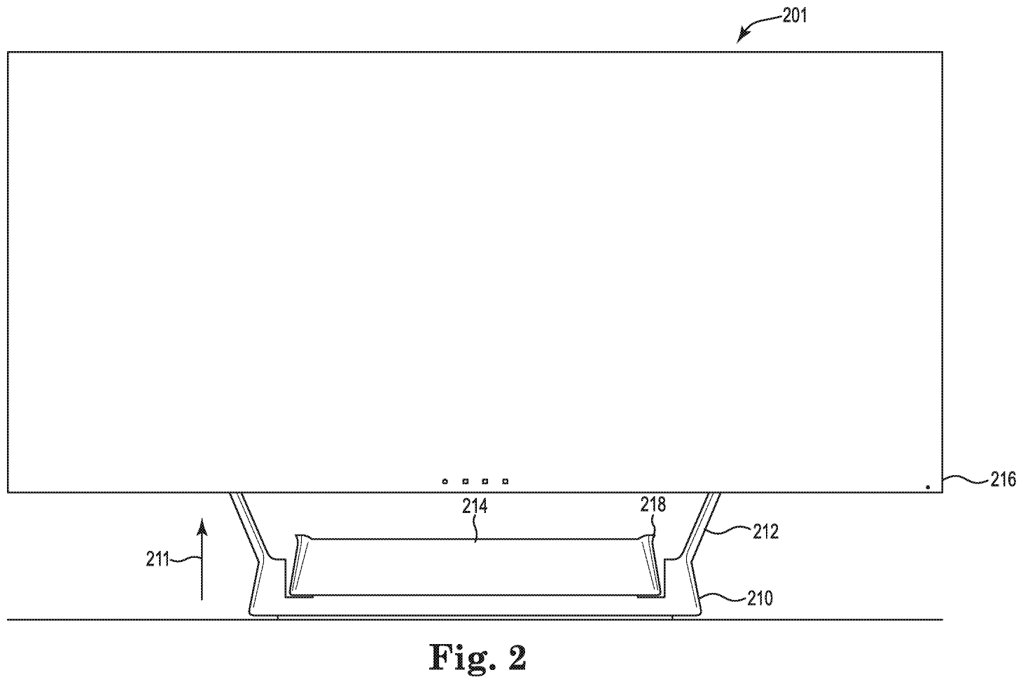

FIG. 2 is an example display stand 201 with an expansion slot consistent with the present disclosure. In some examples, the display stand 201 can include the same or similar elements as display stand 101 as illustrated in FIG. 1. For example, the display stand 201 can include a lid portion 214 that can be opened to provide access to computing components that include an expansion slot.

In some examples, the display stand 201 can include an arm 212 that can be utilized to couple a base portion 210 to a display 216. As described herein, the arm 212 can be utilized to provide a communication pathway between computing components positioned within the base portion 210 to computing components or light sources positioned within the display 216. In some examples, the display stand 201 can be permanently coupled to the display 216. In other examples, the display stand 201 can include a connection interface to be coupled to the display 216. In these other examples, the connection interface can be utilized as a communication pathway between the computing components within the base portion 210 and computing components within the display 216. That is, the display 216 can include a first connection interface and the arm 212 can include a second connection interface that can be coupled to the first connection interface.

In some examples, the base portion 210 can include a lid 214 that can be utilized to access an expansion slot positioned within the base portion 210. In some examples, the lid 214 can include a hinge 218 that can allow the lid 214 to rotate from a closed position to an open position. In some examples, the lid 214 can move in the direction of arrow 211 when the lid 214 is being opened to access the computing components. Thus, the lid 214 can be utilized to access the expansion slot such that an expansion card can be coupled to the computing components positioned within an expansion slot enclosure. As used herein, an expansion slot enclosure can include an enclosure that can store an expansion slot and/or expansion card coupled to the expansion slot.

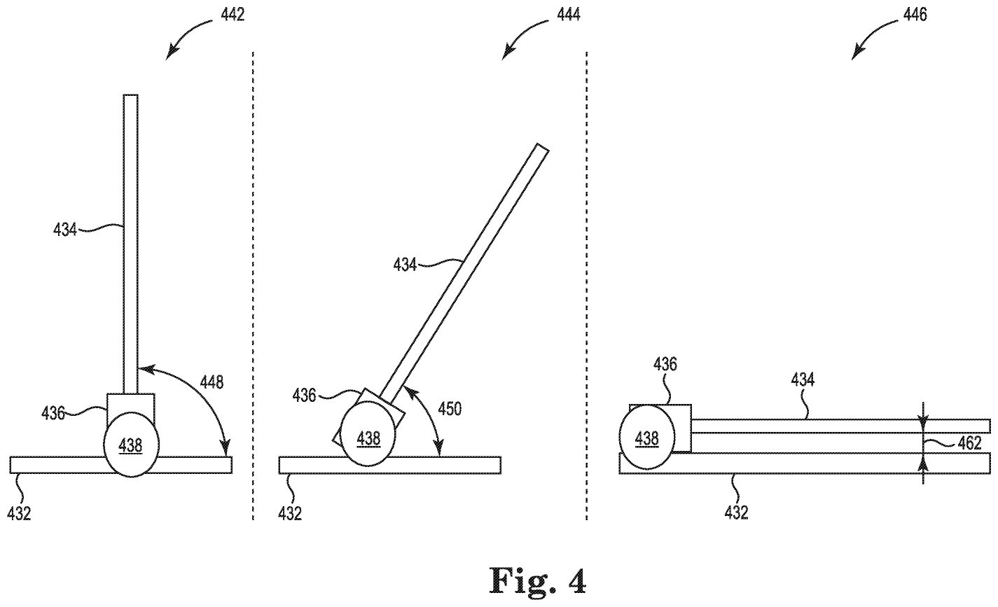

In some examples, the expansion slot positioned within the base portion 210 can be a rotatable expansion slot. As used herein, a rotatable expansion slot can be an expansion slot that can be rotated when an expansion card is coupled to the expansion slot. For example, the rotatable expansion slot can be positioned to receive the expansion card such that the expansion card is positioned substantially perpendicular to the PCB positioned within the base portion 210. In this example, the expansion slot can be rotated such that the expansion card is positioned substantially parallel to the PCB positioned within the base portion 210. In this way, a size or volume of the expansion slot enclosure can be lowered compared to utilizing an expansion slot that positions the expansion card in a position that is substantially perpendicular to the PCB positioned within the base portion 210. The rotation of the expansion slot is further illustrated in FIG. 4.

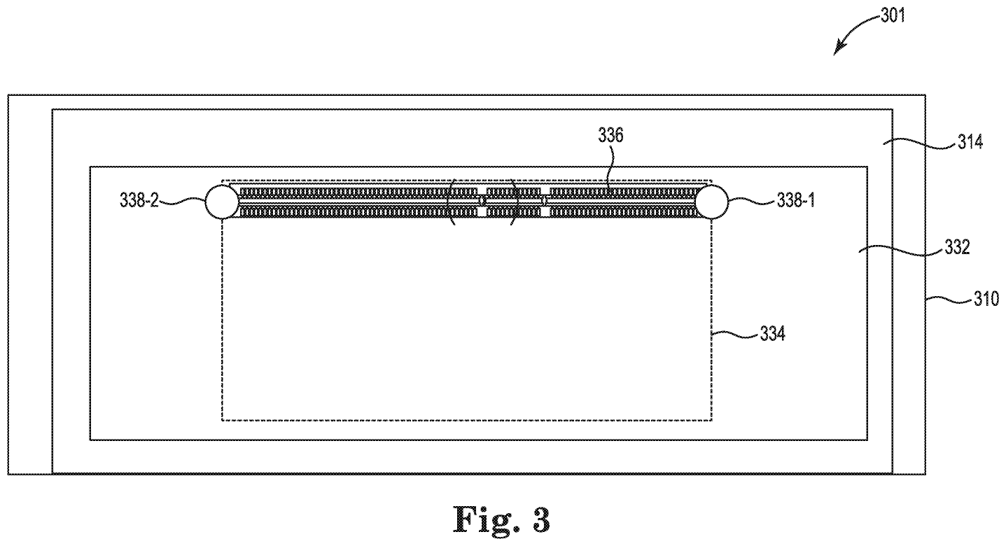

FIG. 3 is an example display stand 301 with an expansion slot 336 consistent with the present disclosure. In some examples, the display stand 301 can include the same or similar elements as display stand 101 as illustrated in FIG. 1 and/or display stand 201 as illustrated in FIG. 2. For example, the display stand 301 can include a base portion 310 that can include a lid 314 that can enclose or provide access to an expansion slot enclosure that includes the expansion slot 336. As described herein, the display stand 301 can be utilized to couple a display (e.g., display 116 as referenced in FIG. 1, etc.) while the display stand 301 is positioned on a surface.

In some examples, the display stand 301 can include computing components. For example, the display stand 301 can include a PCB 332 that can be positioned within the expansion slot enclosure. In some examples, the expansion slot enclosure can be positioned between a floor of the base portion 310 and the lid 314. As described herein, the lid 314 can be rotated on a hinge to gain access to the PCB 332 and/or the expansion slot 336. In some examples, the expansion slot 336 can include an electrical interface for coupling expansion cards to the PCB 332. For example, the expansion slot 336 can be a PCI slot, an AGP type slot, and/or a PCI-Express slot as described herein. In some examples, the expansion slot 336 can be hard wired to the PCB 332. As used herein, hard wired can include a permanent or semi-permanent electrical connection such as a soldered connection. That is, a hard wired connection can be a connection that is embedded within the PCB 332 or soldered to a connection of the PCB 332.

In some examples, the expansion slot 336 can include rotation mechanisms 338-1, 338-2. In some examples, the rotation mechanisms 338-1, 338-2 can be utilized to rotate the expansion slot 336 approximately 90 degrees. For example, the rotation mechanisms 338-1, 338-2 can rotate from a first position to a second position. In this example, the first position can put an expansion card 334 coupled to the expansion slot 336 substantially perpendicular to the PCB 332 and the second position can put the expansion card 334 substantially parallel to the PCB 332 as illustrated in FIG. 3. Thus, the rotation mechanisms 338-1, 338-2 can provide a relatively lower profile by positioning the expansion card 334 substantially parallel with the PCB 332. In some examples, the rotation mechanisms 338-1, 338-2 can allow the expansion slot 336 to rotate to a predetermined position (e.g., height of a tallest component of the PCB 332, etc.).

In some examples, the rotation mechanisms 338-1, 338-2 can be coupled to a hinge mechanism (e.g., hinge 218 as referenced in FIG. 2, etc.). For example, the lid 314 can be moved to an open position or be raised away from the base portion 310. In this example, the rotation mechanisms 338-1, 338-2 can rotate the expansion slot 336 with the rotation of the hinge mechanism. Thus, when the lid 314 is in an open position the expansion slot 336 can be positioned to receive an expansion card substantially perpendicular to the PCB 332 and when the lid 314 is in a closed position the expansion slot 336 can be positioned to align a coupled expansion card 334 substantially parallel with the PCB 332.

FIG. 4 is an example installation of an expansion card 434 to an expansion slot 436 within a display stand consistent with the present disclosure. In some examples, the installation can be utilized to install an expansion card 434 or remove the expansion card 434 from the expansion slot 436. In some examples, the installation can include a plurality of steps 442, 444, 446. In some examples, the plurality of steps 442, 444, 446 may be performed sequentially, non-sequentially, and/or in reverse of the numerical order. In some examples, the installation can include a plurality of additional or fewer steps as described herein.

At step 442, the installation can include inserting or coupling an expansion card 434 into an expansion slot 436 that is coupled to a PCB 432 (e.g., computing component, PCA, etc.). In some examples, the expansion slot 436 can be an express PCI slot and the expansion card can be an express PCI card. In these examples, a connection interface of the PCI card can be inserted into a connection interface of the PCI slot. In some examples, locking mechanism can be utilized to secure the connection between the expansion card 434 and the expansion slot 436.

In some examples, the expansion slot 436 can be coupled to a rotation mechanism 438. As described herein, a rotation mechanism 438 can be utilized to rotate the expansion slot 436 in the directions of double arrow 448, In some examples, the rotation mechanism 438 can be activated when the expansion card 434 is inserted into the expansion slot 436. For example, the rotation mechanism 438 can be locked when an expansion card 434 is not inserted or coupled to the expansion slot 436 and the rotation mechanism 438 can be unlocked when the expansion card 434 is inserted or coupled to the expansion slot 436. In other examples, the rotation mechanism 438 can be coupled or synchronized with a lid of the expansion slot enclosure. For example, movement of the lid in the directions of double arrow 448 can simultaneously or substantially simultaneously move the expansion slot 436 via the rotation mechanism 438.

At step 444, the installation can include rotating the expansion card 434 and expansion slot 436 toward a surface of the PCB 432 utilizing the rotation mechanism 438. In some examples, the rotation of the expansion card 434 and expansion slot 436 can create an angle 450 between the surface of the expansion card 434 and the PCB 432. In some examples, the angle 450 can be an angle between 90 degrees and 0 degrees. For example, the angle 450 can be an angle between 35 degrees and 55 degrees.

At step 446, the installation can include positioning the expansion card 434 in a position that is substantially parallel with the PCB 432. As described herein, step 446 can reduce the height profile of the computing components within the expansion slot enclosure within a base portion of a display stand. For example, a height of the PCB 432 and expansion card 434 can be greater at step 442 than at step 446. In some examples, the expansion card 434 can be rotated in the direction of the PCB 432 to a predetermined height 452.

In some examples, the predetermined height 452 can be a height of a component coupled to the PCB 432. For example, a height of a plurality of components coupled to the PCB 432 can be determined and a component with a greatest height can be identified. In this example, the predetermined height 452 can accommodate the identified component with the greatest height. In other examples, the predetermined height 452 can be based on a height of the expansion slot enclosure when the lid is in a closed position. For example, the height of the expansion slot enclosure can be greater than a height of the PCB 432 and expansion card 434 at the predetermined height 452. In this way, the volume of the expansion slot enclosure can be relatively smaller than previous systems.

The figures herein follow a numbering convention in which the first digit corresponds to the drawing figure number and the remaining digits identify an element or component in the drawing. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure and should not be taken in a limiting sense. Further, as used herein, “a number of” an element and/or feature can refer to any number of such elements and/or features,

What is claimed:

1. A display stand, comprising:
a base portion that includes an expansion slot;
an attachment mechanism to couple a display to the base portion; and
a permanent connection to couple the expansion slot to the display.

2. The display stand of claim 1, wherein a first portion of the permanent connection is positioned within the base portion and a second portion of the permanent connection is positioned through the attachment mechanism.

3. The display stand of claim 1, wherein the expansion slot is to receive a graphics expansion card to generate graphics for the display.

4. The display stand of claim 1, comprising a connection interface to couple the display to a computing device, wherein the expansion slot is to receive a graphics expansion card to generate graphics provided by the computing device.

5. The display stand of claim 1, wherein the base portion includes an enclosure that surrounds the expansion slot.

6. A system comprising:
a display, comprising a first connection interface; and
a display stand, comprising:
a second connection interface couplable to the first connection interface;
an expansion slot enclosure;
an expansion slot positioned within the expansion slot enclosure;
a connection cable to couple the second connection interface to the expansion slot.

7. The system of claim 6, comprising an attachment mechanism to couple the display to the display stand, wherein the attachment mechanism is to secure a connection between the first connection interface and the second connection interface.

8. The system of claim 6, wherein the expansion slot is to receive a graphics expansion card to generate graphics on the display when the first connection interface is coupled to the second connection interface.

9. The system of claim 6, comprising an electrical connection coupled to the display, wherein the electrical connection provides power to the expansion slot.

10. The system of claim 6, wherein the expansion slot is rotatable 90 degrees when an expansion card is inserted into the expansion slot.

11. The system of claim 10, wherein the expansion slot is rotatable with a lid of the expansion slot enclosure.

12. The system of claim 6, wherein the expansion slot enclosure is positioned within a base portion of the display stand.

13. A device, comprising:
an expansion slot enclosure to enclose a graphics expansion slot, wherein the graphics expansion slot is to receive a graphics expansion card;
a base portion to enclose the expansion slot enclosure;
a display arm coupled to the base portion;
an attachment mechanism coupled to the display arm to couple a display to the display arm; and
a connection interface to couple the display to the graphics expansion slot to allow the graphics expansion card to generate graphics on the display when the graphics expansion card is coupled to the graphics expansion card slot.

14. The device of claim 13, wherein the connection interface couples the graphics expansion slot to a printed circuit board (PCB) of the display.

15. The device of claim 13, wherein the expansion slot enclosure is physically separate from a computing device coupled to the display.
